(19) United States
(12) Patent Application Publication
(10) Pub. No.: US 2017/0338388 A1
(43) Pub. Date: Nov. 23, 2017

(54) ULTRAVIOLET LIGHT-EMITTING DIODE PACKAGING STRUCTURE

(71) Applicant: Unistars Corporation, Zhudong Township (TW)

(72) Inventors: SHANG-YI WU, Hsinchu City (TW); HSIN-HSIEN HSIEH, Zhongli City (TW)

(21) Appl. No.: 15/435,250

(22) Filed: Feb. 16, 2017

(30) Foreign Application Priority Data
May 23, 2016 (TW) 105116004

(51) Int. Cl. H01L 33/60; H01L 33/48

(52) U.S. Cl. CPC H01L 33/60; H01L 33/486

(57) ABSTRACT

The present invention provides a packaging structure of ultraviolet light-emitting diodes, comprising: a substrate having an electrode; an UV LED chip disposed on the substrate and electrically connected to the electrode; a transparent cap covering the substrate and the chip; an adhesive layer disposed between the substrate and the transparent cap; and a light reflective layer disposed between the adhesion layer and the transparent cap, wherein the transparent cap is fixed onto the substrate via the light reflective layer and the adhesion layer. And the light reflective layer of the case is made by metal, the adhesive layer is optional.

### FIELD OF THE INVENTION

The present invention relates to a packaging structure of a light-emitting diode (LED), especially to a packaging structure of an ultraviolet light-emitting diode (UV LED).

### BACKGROUND OF THE INVENTION

A light emitting diode (LED), which is a semiconductor light source, shows benefits of energy conservation, lower electrical power consumption, higher efficiency, shorter activation time, longer operation life, mercury free, environmental protection, and etc. obviously. And thus, LED has been widely used in general and commercial lighting applications. In order to increase operation life of LED, a robust package methodology is necessary for better protection. Not only materials of a LED package structure are limited (i.e. transparent material is required for light emitting), but also structures and packaging methods are essential.

In conventional packaging technique, a LED chip is bonded on a patterned non-transparent substrate and electrically connected to the substrate via metal wires. A transparent material is then disposed and covers the entire LED chip, the metal wires, and the substrate; and afterward, a curing process is performed to finish packaging process. Transparent materials are required for light emitting and transmittance in a LED package, and thus choices of materials used in LED packages are very limited. Conventional polymer colloids used in LED packages degrade easily under exposure to UV light (wavelength less than 450 nm) for a certain time period, and it results in decreases in light transmittance rate and loss of adhesiveness. Therefore, not only performances of a conventional LED become worse with the increasing of utilization hours, but also an operation life of a conventional LED is reduced due to the worsening or degradation of packaging protection.

In order to improve the abovementioned issues, manufacturers have developed silica glass, which has better light-transmittance rate under exposure to UV light, as a material for optical lens in UV LED packages in the current market in order to have more stable and longer-lasting product efficiency. However, it still requires colloid/glue to fix the silica glass onto the substrate. The colloid/glue degrades after a certain time period of use. It leads to the damage of sealing quality and results in shorter lifetime of an UV LED light source. Thus, the conventional packaging structures cannot adequately provide UV LED light sources a long-term protection.

Therefore, a subject of the present invention is to improve protection of an UV LED packaging structure even under long-term exposure to UV light without affecting transmittance rate of the light source.

### SUMMARY OF THE INVENTION

The present invention provides an ultraviolet light-emitting diode (UV LED) packaging structure, comprising: a substrate having an electrode; an UV LED chip disposed on the substrate and electrically connected to the electrode; a transparent cap disposed on and covered the substrate and the UV chip; a light reflective layer disposed between the substrate and the transparent cap; and an adhesion layer disposed between the substrate and the light reflective layer, wherein the transparent cap is fixed on the substrate by the light reflective layer and the adhesion layer.

In one embodiment of the present invention, wherein the light reflective layer adheres to the transparent cap.

In one embodiment of the present invention, wherein the light reflective layer is made of metal.

In one embodiment of the present invention, wherein the adhesive layer is made of metal and eutectic bonding with the light reflective layer.

In one embodiment of the present invention, wherein the adhesive layer is made of polymer resin and adhesively bonded to the light reflective layer.

In one embodiment of the present invention, wherein the transparent cap has a first trench and the UV LED chip is inside the first trench.

In one embodiment of the present invention, wherein the transparent cap has a surface which contacts with (adheres to) the substrate via the light reflective layer and the adhesion layer, and the surface inside the trench is separated from the substrate, the light reflective layer and the adhesion layer.

In one embodiment of the present invention, wherein the substrate further comprises a cavity structure surrounding the UV LED chip.

In one embodiment of the present invention, wherein the substrate comprises a carrier and the patterned electrodes. The patterned electrodes penetrate through the carrier and electrically connect two opposite sides of the carrier.

In one embodiment of the present invention, wherein the transparent cap has a second trench and the UV LED chip and the cavity structure are inside the second trench.

In one embodiment of the present invention, wherein the adhesion layer is fixed on and contacted with one of the carrier and the electrode of the substrate.

In one embodiment of the present invention, wherein the transparent cap has a planar surface close to the substrate.

In one embodiment of the present invention, wherein the adhesive layer is directly contacted with the top surface of the cavity structure.

In one embodiment of the present invention, wherein a side of the cavity structure has a concaved portion formed thereon, and a side of the transparent cap close to the cavity structure has a protrusion portion formed thereon corresponding to the concaved portion.

In one embodiment of the present invention, wherein the protrusion portion and the concaved portion are ring-shapes.

In one embodiment of the present invention, wherein the adhesive layer is in the concaved portion and the light reflective layer is on the protrusion portion.

In one embodiment of the present invention, wherein the adhesive layer is only disposed on a bottom surface of the concaved portion, and the light reflective layer is only disposed on a top surface of the protrusion portion.

In one embodiment of the present invention, wherein a light wavelength emitted from the UV LED chip is below 450 nm.

In one embodiment of the present invention, wherein the transparent cap has a convex surface away from the substrate.

Another aspect of the present invention provides an ultraviolet light-emitting diode (UV LED) packaging structure, comprising: a substrate having electrodes; an UV LED chip disposed on the substrate and electrically connected to the electrodes; a transparent cap disposed on and covering the substrate and the UV chip; and a metal layer disposed between the substrate and the transparent cap, wherein the transparent cap is eutectic bonding with the electrodes.

In one embodiment of the present invention, wherein the transparent cap has a trench, and the UV LED chip is inside the trench.

In one embodiment of the present invention, wherein the transparent cap has a surface which contacts to the substrate, and the surface inside the trench is separated from the substrate.

In one embodiment of the present invention, wherein the substrate comprises a carrier and the patterned electrodes, and the patterned electrodes penetrate through the carrier to electrically connect two opposite sides of the carrier; and the metal layer is separated from the carrier.

In one embodiment of the present invention, wherein the transparent cap has a convex surface away from the substrate.

Accordingly, the present invention provides an UV LED packaging structure suitable for all common LED chips in the market, especially for UV LED chips having a wavelength below 450 nm, in order to prevent problems of degradation, provide better and longer protection, and extend life times of the products.

### BRIEF DESCRIPTION OF THE DRAWINGS

The present invention will become more readily apparent to those ordinarily skilled in the art after reviewing the following detailed descriptions and accompanying drawings, in which:

FIG. 1A is a cross-sectional view of the packaging structure 10 according to an embodiment of the present invention;

FIG. 1B is a top view of the packaging structure 10;

FIG. 2 is a cross-sectional view of the packaging structure 11 according to an embodiment of the present invention;

FIG. 3A is a cross-sectional view of the packaging structure 20 according to an embodiment of the present invention;

FIG. 3B is a top view of the packaging structure 20;

FIG. 4A is a cross-sectional view of the packaging structure 30 according to an embodiment of the present invention;

FIG. 4B is a top view of the packaging structure 30;

FIG. 5A is a cross-sectional view of the packaging structure 40 according to an embodiment of the present invention;

FIG. 5B is a top view of the packaging structure 40; and

FIG. 6 is a cross-sectional view of the packaging structure 50 according to an embodiment of the present invention.

### DETAILED DESCRIPTION OF PREFERRED EMBODIMENTS

The present invention provides an ultraviolet light-emitting diode (UV LED) packaging structure in order to prevent problems of degradation according to conventional packaging structures and provide better and longer protection to UV LED chips, and therefore the present invention can provide a UV light source with longer lifetime. It is to be noted that the following descriptions of preferred embodiments of this invention are presented herein for purpose of illustration and description only but not intended to be exhaustive or to be limited to the precise form disclosed.

In the following illustration, the element arranged repeatedly is described in word “one”, “a” or “an” for simpler explanation; and an arrange of number represented by “˜” includes both ends of the numbers as minimum and maximum values. However, one skilled in the art should understand the practical structure and arrangement of each element based on the following illustration and figures provided in the present application.

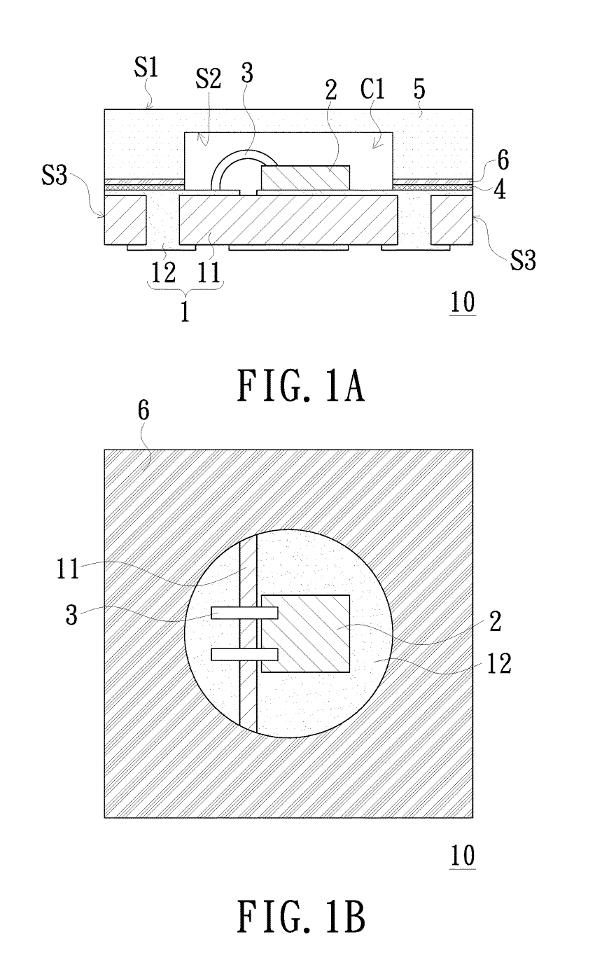

FIGS. 1A and 1B shows a packaging structure 10 according to an embodiment of the present invention, wherein FIG. 1A is a cross-sectional view and FIG. 1B is a top view of the packaging structure 10. The packaging structure 10 is applied to a conventional wire-bonding LED chip without a cavity structure. As shown in FIGS. 1A and 1B, a substrate 1 comprises an (insulating) carrier 11 and a plurality of electrodes 12 (including at least a negative electrode and a positive electrode), the electrodes 12 are formed on the (insulating) carrier 11 and provides electrical connection between two opposite sides of the carrier 11. In this embodiment, the electrodes 12 penetrate through the carrier 11. The carrier 11 is made of ceramic or dielectric material, and the electrodes 12 are majorly or substantially made of copper in this embodiment; however, it does not intend to limit the present invention, and other suitable materials can be used. An ultraviolet light-emitting diode (UV LED) chip 2 is bonded or placed onto the substrate 1, an electrode (not shown) of the UV LED chip 2 is electrically connected to one of the electrode 12 through a metal wire 3, and an another electrode (not shown) of the UV LED chip 2 is electrically connected with another electrode 12 by direct contact. In this embodiment, the electrodes 12 cover most of the carrier 11; however, in other embodiments of the present invention, a covering area of the electrodes 12 on the carrier 11 can be adjusted. Then an adhesive layer 4 is formed on the substrate 1 directly contacting with the electrodes 12 and separated from the carrier 11. The adhesive layer 4 surrounds (revolves around or encircles) the UV LED chip 2 and the metal wire 3. A transparent cap 5 is formed by molding, etching or mechanical shaping. A light reflective layer 6 is then formed on the transparent cap 5 corresponding to (a region) where the adhesive layer 4 is disposed on the substrate 1, and then the transparent cap 5 along with the light reflective layer 6 are disposed onto the substrate 1 covering both the substrate 1 and the UV LED chip 2. In this embodiment, the transparent cap 5 is made of silica glass or Quartz glass, and a plurality of trenches C1 is formed, by molding, etching or mechanical shaping, on the transparent cap 5 corresponding to where the UV LED chips 2 are on the substrate 1 in order to position each of the UV LED chips 2 in each of the trenches C1 to provide protection (FIGS. 1A and 1B show only one UV LED chip 2 and a portion of the substrate 1 for brief illustration only, but not intended to limit the present invention). The transparent cap 5 has a top surface S1 away from the substrate 1 and a bottom surface S2 close to the substrate 1. The top surface S1 is planar, the bottom surface S2 is non-planar, and a portion of the bottom surface S2 contacts with the adhesion layer 4 via the reflective layer 6 on the substrate 1, and a portion of the bottom surface S2 inside the trenches C1 is separated from the substrate 1, the adhesion layer 4 and the light reflective layer 6. The adhesive layer 4 is made of polymer resin in this embodiment working or functioning as glue in order to fix or bond the transparent cap 5 with the substrate 1. The adhesive layer 4 covers the entire area outside the trench C1 of the substrate 1 in this embodiment, and the light reflective layer 6 covers the entire adhesive layer 4. However, in other embodiment, the adhesive layer 4 and the light reflective layer 6 only have to cover portions of the substrate 1 that can provide enough bonding capability for fixing the transparent cap 5 on the substrate 1.

The inventors discover that some of UV light within the transparent cap generates internal total reflection, and result in the degradation of colloid/glue in the conventional packaging structure of an UV LED chip. And thus, it is difficult to avoid from UV exposure for the glue/colloid by simply adjusting positions of glue/colloid relative to the UV LED chip in the conventional packaging structure. Therefore, the present invention provides a packaging structure to dispose the light reflective layer 6 in-between the adhesive layer 4 and the transparent cap 5. The light reflective layer 6 can reflect UV light completely from the transparent cap 5 away and avoid UV exposure to the adhesive layer 4. The present invention can improve the protection property of a packaging structure of UV LED chip and extend its operation life without affecting a light transmittance rate of the packaging structure.

The present invention provides an ultraviolet light-emitting diode (UV LED) packaging structure, at least comprising: a substrate having a plurality of electrodes, wherein the electrodes are exposed on a surface of the substrate in order to provide electrical connection; an UV LED chip placed on the substrate and electrically connected to the electrodes; a transparent cap disposed on and covered the substrate and the UV LED chip; an adhesive layer disposed between the substrate and the transparent cap; and a light reflective layer disposed between the transparent cap and the adhesive layer, wherein the transparent cap is fixed on the substrate via the light reflective layer and the adhesive layer.

Materials of the transparent cap of the present invention can be any UV-resistant transparent materials, for examples, oxide transparent ceramic materials including silica glass, quartz materials, aluminum oxide, magnesium oxide, beryllium oxide, yttrium oxide, yttrium oxide-zirconium dioxide, and combination thereof, or non-oxide transparent ceramic materials including gallium arsenide (GaAs), zinc sulfide (ZnS), zinc selenide (ZnSe), magnesium fluoride (MgF₂), calcium fluoride (CaF₂) and etc. The light reflective layer is selected from metal, such as pure aluminum, pure gold, pure copper or alloy of any combination of the above mentioned metals. Moreover, the adhesive layer is selected from polymer resins, as in the above embodiment, or metals. Thus, the transparent cap can be fixed onto the substrate by adhesively bonding or by metal eutectic bonding. In the embodiments of the present invention which adopt metal eutectic bonding, the glue/colloid is not used for adhesion and glue/colloid degradation problems can then be avoided.

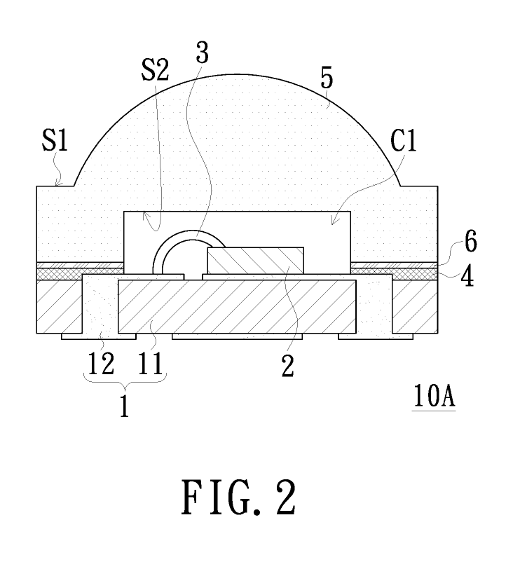

The packaging structure 10 in the above embodiment as shown in FIGS. 1A and 1B is applied to a conventional wire-bonding LED chip without a cavity structure, and the electrodes 12 of the substrate 1 is formed by the following steps. First, an electrode layer is formed and patterned on the top and bottom surfaces of the carrier 11, plurality of through holes are then formed on the carrier 11, and then conductive plugs are formed inside the through holes connecting the electrode layer on the top and bottom surfaces of the carrier 11. Thus, the electrodes 12 can be formed on and penetrate through the carrier 11 in order to provide electrical connection between the top and the bottom sides of the carrier 11. However, in other embodiments of the present invention, an electrode layer is firstly formed and patterned on the top and bottom surfaces of the carrier 11, and then a conductive layer is formed on lateral sides S3 of the carrier 11 after the carrier 11 is cut into chips (instead of penetrating through the carrier 11 as shown in the above embodiment), and thus the conductive layer and the electrode layer together to form the electrodes 12 for electrical connection between the two opposite sides of the substrate 1. Moreover, in order to adjust the light emitting angle, another embodiment of the present invention as shown in FIG. 2, a packaging structure 10A having a similar structure to the packaging structure 10 but with a convex top surface S1 of the transparent cap 5 is provided (elements with the similar functions use the same element numbers as FIGS. 1A and 1B for easier understanding). In other embodiments, shapes of the transparent cap 5 can be adjusted depends on different requirements. Also, the packaging structure 10A as shown in FIG. 2 has a smaller area of the carrier 11 covered by the electrodes 12 than the packaging structure 10 as shown in FIG. 1A, and the adhesive layer 4 disposed on the substrate 1 directly contacts to the electrodes 12 and optionally also the carrier 11 as shown in FIG. 2 depending on different patterns of the electrodes 12 in different applications. In other embodiments of the present invention, the adhesive layer 4 on the substrate 1 covers different area depending on covering area of the electrode 12 to the carrier 11, for example, the adhesive layer 4 contacts to only the carrier 11 or only the electrodes 12.

The above embodiments are applied to conventional wire-bonding LED chips without cavity structures, but it is not intended to limit the present invention. Based on the spirits and concepts of the present invention, packaging structures are not limited thereof. The following provides embodiments of the present invention applied to a conventional wire-bonding LED chip with a cavity structure.

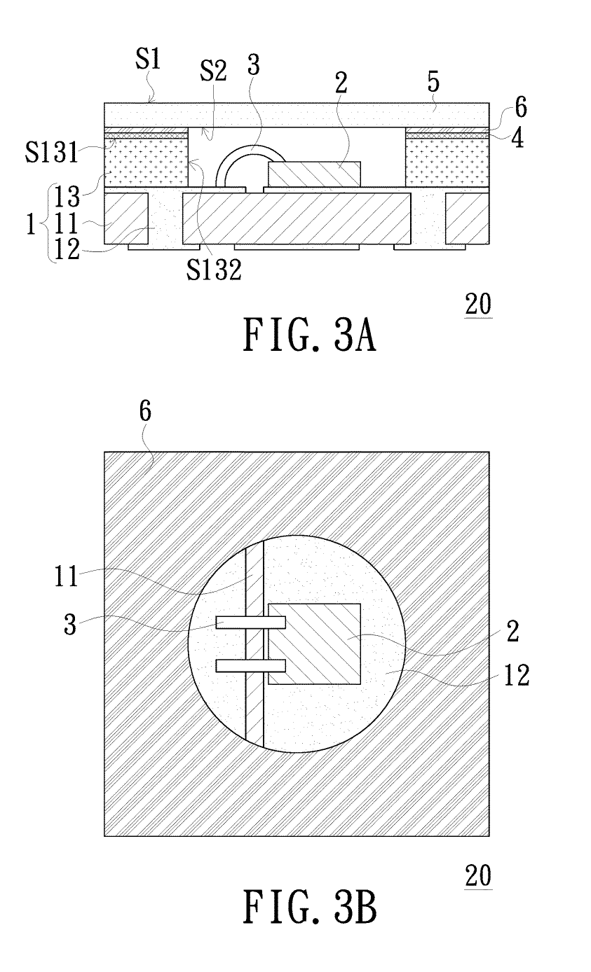

FIGS. 3A and 3B shows a packaging structure 20 according to an embodiment of the present invention, wherein FIG. 3A is a cross-sectional view and FIG. 3B is a top view of the packaging structure 20. For simple illustration and easier understanding, elements with similar functions as illustrated above will be named the same element numbers. As shown in FIGS. 3A and 3B, a substrate 1 comprises a carrier 11, a plurality of electrodes 12, and a cavity structure 13, wherein the electrodes 12 are fixed on and penetrate through the carrier 11 in order to provide electrical connection between two opposite sides of the carrier 11. The cavity structure 13 is disposed on a side of the carrier 11 and defines at least one rounded through hole, and the cavity structure 13 is on the electrodes 12 and partially contacts with the carrier 11 (not shown). And as shown in FIG. 3B, a space is formed inside the cavity structure 13 and defined by the cavity structure 13 and the substrate 1; and in this embodiment, the space is circular. Shapes, sizes, and covering areas of the space are not limited. Then an UV LED chip 2 is placed or bonded onto the substrate 1 inside the cavity structure 13. An electrode of the UV LED chip 2 is electrically-connected to a portion of one of the electrodes 12 through the metal wire 3 at the place where the electrodes 12 is not covered by the cavity structure 13, and the other electrode of the UV LED chip 2 is electrically connect to the electrode 12 by direct contact. Then an adhesive layer 4 is formed on a top surface S131 of the cavity structure 13 surrounding/encircling the UV LED chip 2 and the metal wire 3. A light reflective layer 6, made of metal, is deposited on a portion of a bottom surface S2 of the transparent cap 5 corresponding to where the adhesive layer 4 is. In other words, the size and position of the light reflective layer 6 substantially matches that of the adhesive layer 4 under top view. In this embodiment, a top surface S1 and a bottom surface S2 of the transparent cap 5 are both planar. The light reflective layer 6 correspondingly covers the adhesive layer 4, and the covering areas of the light reflective layer 6 and the adhesive layer 4 are not limited. In this embodiment, the light reflective layer 6 and the adhesive layer 4 respectively cover the entire top surface S131 of the cavity structure 13, as shown in FIG. 3B. The cavity structure 13 is made of ceramic material(s), and a reflecting layer (can be made of metal) is optionally formed on an inner surface S132 of the cavity structure 13 for better light emitting efficiency and brightness. In other embodiments of the present invention, a metal layer (not shown) is formed on the inner surface S132 for better brightness and light concentration or condensing and also formed on the top surface S131 for providing adhesion so that the portion of the metal layer on the top surface S131 can be use (or serve) as the adhesive layer 4 for eutectic bonding to the light reflective layer 6.

In order to adjust the light emitting angle, the top surface S1 of the transparent cap 5 can be convex or to be adjusted based on different requirements. Moreover, FIGS. 3A and 3B show the electrodes 12 of the packaging structure 20 covers most of the carrier 11 and is fixed on and penetrates through the carrier 11 to provide electrical connection between the top and the bottom surfaces of the carrier 11. However, in other embodiments of the present invention, an electrode layer is first formed and patterned on the two opposite sides of the carrier 11 and then a conductive layer is formed on lateral sides of the carrier 11 after chip cutting process, and thus the conductive layer and the electrode layer together to form the electrodes 12 for electrical connection between the two sides of the substrate 1 by disposing a portion of the electrodes 12 on lateral sides of the carrier 11. In this embodiment, the cavity structure 13 covers on and directly contacts with the electrodes 12; however, the covering area of the electrodes 12 on the carrier 11 can be varied, and for example, the cavity structure 13 can directly contact with the carrier 11 only or directly contact with the electrode 12 only or directly contact with both the carrier 11 and the electrode 12.

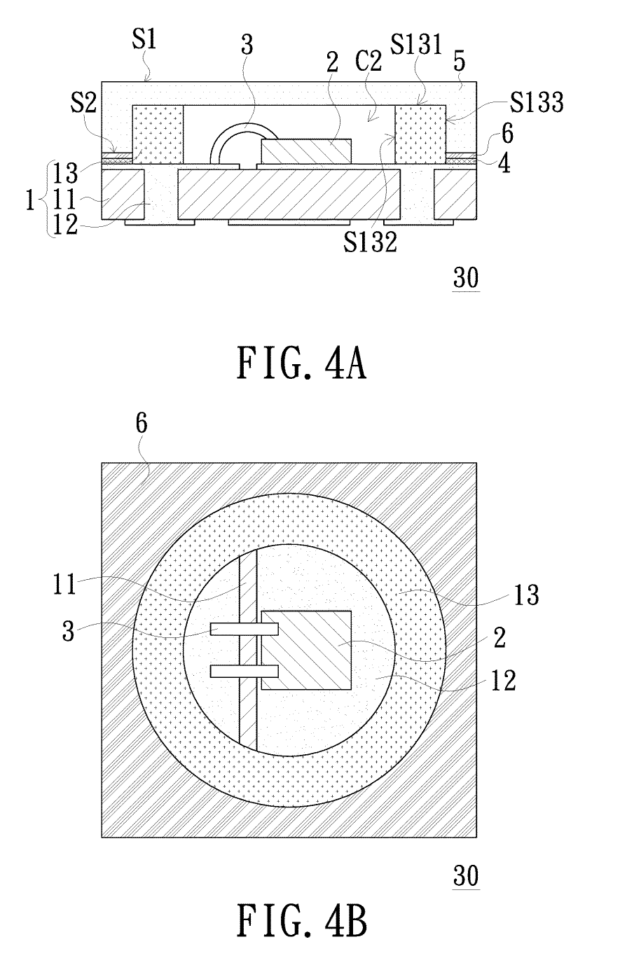

FIGS. 4A and 4B shows a packaging structure 30 according to an embodiment of the present invention, wherein FIG. 4A is a cross-sectional view and FIG. 4B is a top view of the packaging structure 30. For simple illustration and easier understanding, elements with similar functions as illustrated above will be named same element numbers. As shown in FIGS. 4A and 4B, a substrate 1 comprises a carrier 11, an electrode 12, and a cavity structure 13, wherein the electrode 12 is fixed on and penetrates through the carrier 11 in order to provide electrical connection between two opposite sides of the carrier 11. The cavity structure 13 is a ring shape and disposed on a side of the carrier 11, and in this embodiment, the cavity structure 13 is placed on the electrodes 12 and separated from the carrier 11. And as shown in FIG. 4B, a space is formed inside the cavity structure 13 defined by the cavity structure 13 and the substrate 1, and in this embodiment, the area enclosed by the cavity structure 13 is circular in shape. Shapes, sizes, and covering areas of the space are not limited. Then an UV LED chip 2 is fixed onto the substrate 1 inside the cavity structure 13. An electrode (not shown) of the UV LED chip 2 is electrically connected to a portion of the electrodes 12 exposed by the cavity structure 13 via a metal wire 3, and the other electrode (not shown) of the UV LED chip 2 is electrically connected to the electrode 12 by direct contact. Then an adhesive layer 4 is formed on the substrate 1 at the place where that is not covered by the cavity structure 13 and is outside the cavity structure 13. So the UV LED chip 2 and the metal wire 3 are surrounded/encircled by the adhesive layer 4. The transparent cap 5 can be formed as required shapes by molding, etching or mechanical shaping, and then a light reflective layer 6 is formed on the transparent cap 5 corresponding to where the adhesive layer 4 disposed on the substrate 1. After that, the transparent cap 5 and the light reflective layer 6 are fixed onto the substrate 1 covering both the substrate 1 and the UV LED chip 2. In this embodiment, a plurality of trenches C2 is formed on the transparent cap 5 corresponding to where the UV LED chips 2 and the (surrounding) cavity structure 13 are on the substrate 1 in order to position every UV LED chip 2 and the (surrounding) cavity structure 13 together in every trench C2 (FIGS. 4A and 4B show only one UV LED chip 2, one (surrounding) cavity structure 13 and portions of the substrate 1 for brief illustration only, but not intend to limit the present invention). The transparent cap 5 covers the substrate 1 and the UV LED chip 2 to make the UV LED chip 2 and the cavity structure 13 inside the trench C2, and it is preferably that a portion of the bottom surface S2 of the transparent cap 5 inside the trench C2 is contacted with and engaged to the cavity structure 13 for better and stronger protection. As shown in FIG. 4A, a top surface S131 and an outer surface S133 of the cavity structure 13 contact with a portion of the bottom surface S2 of the transparent cap 5 inside the trench C2. It is optional to include a reflecting layer (not shown) or a metal layer (not shown) covering on an inner surface S132 of the cavity structure 13 for better light emitting efficiency.

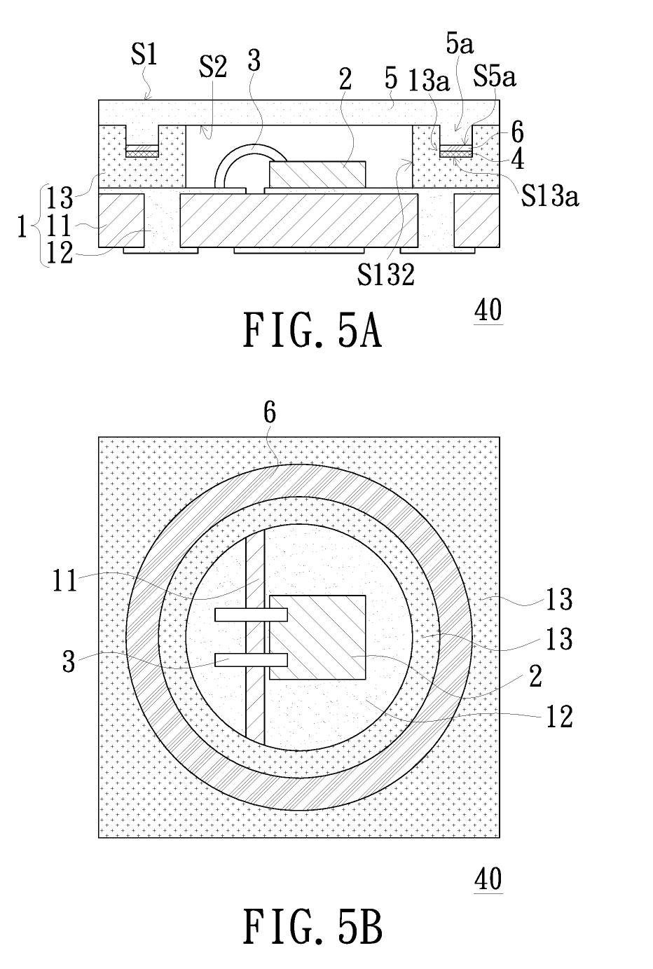

FIGS. 5A and 5B shows a packaging structure 40 according to an embodiment of the present invention, wherein FIG. 5A is a cross-sectional view and FIG. 5B is a top view of the packaging structure 40. For simple illustration and easier understanding, elements with similar functions as illustrated above will be named the same element numbers. As shown in FIGS. 5A and 5B, a substrate 1 comprises a carrier 11, an electrode 12, and a cavity structure 13, wherein the electrode 12 is fixed on and penetrates through the carrier 11 in order to provide electrical connection between two opposite sides of the carrier 11. The cavity structure 13 in this embodiment is fixed on the electrode 12 and separated from the carrier 11. As shown in FIG. 5B, the cavity structure 13 has a circular through hole, and a cylinder-shaped space is defined by the inner sidewall S132 of the cavity structure 13 and the substrate 1. The cavity structure 13 covers most of the substrate 1 except for the portion of the substrate 1 occupy by the space, for providing stronger protection to an UV LED chip 2. Then the UV LED chip 2 is placed onto the substrate 1 inside the cavity structure 13. An electrode (not shown) of the UV LED chip 2 is electrically connected to a portion of the electrode 12 exposed by the cavity structure 13 through a metal wire 3, and the other electrode (not shown) of the UV LED chip 2 is electrically connected to the electrode 12 by direct contact. A side of the cavity structure 13 away from the substrate 1 and close to the transparent cap 5 has a concaved portion 13a formed thereon, and a side of the transparent cap 5 close to the cavity structure 13 has a protrusion portion 5a formed thereon corresponding to the concaved portion 13a. An adhesive layer 4 is formed in the concaved portion 13a of the cavity structure 13, and a light reflective layer 6 is formed on the protrusion portion 5a. More specifically, in this embodiment, the adhesive layer 4 is only disposed on a bottom surface S13a of the concaved portion 13a, and the light reflective layer 6 is only disposed on a top surface S5a of the protrusion portion 5a. When the transparent cap 5 is embedded with and fixed on the cavity structure 13, the cavity structure 13 can shield the adhesive layer 4 (located inside) from UV exposure directed from the UV LED chip 2, and the light reflective layer 6 on the adhesive layer 4 can prevent the adhesive layer 4 from UV exposure directed from total reflection inside the transparent cap 5. Thus, the packaging structure 40 as shown in FIGS. 5A and 5B can have double protection and prevention of degradation, and better and longer operation life of an UV light source can be achieved. In this embodiment, the concaved portion 13a and the protrusion portion 5a are both circular rings in shape, but it is not intended to limit the present invention. Moreover, it is optional to include a reflecting layer or a metal layer (not shown) covering on an inner surface S132 of the cavity structure 13 for better light emitting efficiency.

The packaging structures 30 and 40 both provide better shielding by placing at least a portion of the cavity structure 13 between the UV LED chip 2 and the adhesive layer 4, and thus the possibility of UV light projecting or radiating on the adhesive layer 4 are reduced. Moreover, the light reflective layer 6 is disposed in-between the adhesive layer 4 and the transparent cap 5 to prevent UV light projecting on the adhesive layer 4 due to internal total reflection inside the transparent cap 5, and thus double shielding can be achieved. The electrode 12 covers most of the carrier 11, and the adhesive layer 4 is directly on the electrode 12 in both cases/embodiments of the packaging structures 30 and 40. In other embodiments of the present invention, a contacting area of the adhesive layer 4 on the substrate 1 can be adjusted. For example, the adhesive layer 4 can directly contact with only the carrier 11 or directly contact only the electrode 12 or directly contact both the carrier 11 and the electrode 12. Moreover, materials of the adhesive layer 4, transparent cap 5 and light reflective layer 6 are same as above illustrated in other embodiments. And shapes of the top surface S1 of the transparent cap 5 and covering areas of the electrodes 12 are both adjustable depending on different cases.

As the concepts of the present invention illustrated above in order to solve the problem of the degradation of adhesion between a cap and a substrate, the present invention provides other embodiments as illustrated below that packaging structures have no adhesive layer 4. The transparent cap 5 is fixed onto the substrate 1 by eutectic bonding between the light reflective layer 6 and a portion of the electrode 12.

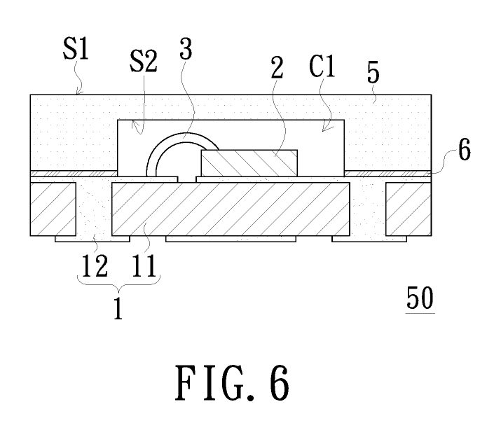

As described above, the adhesive layer 4 can be made of metal. Due to the electrode 12 in different cases/embodiments may have small or large covering area on the carrier 11, and in cases/embodiments an overlapped portion of the electrode 12 with the light reflective layer 6 (made of metal in these cases) is not large enough for fixing the transparent cap 5 (due to having smaller area available for eutectic bonding), it is preferably to deposited an adhesive layer 4 made of metal on the substrate 1 first and then performing eutectic bonding process. However, the adhesive layer 4 is not necessary in the cases where the electrode 12 has a large covering area on the carrier 11. As shown in FIG. 6, a metal light reflective layer 6 and an electrode 12 are eutectic bonded to fix the transparent cap 5 on the substrate 1. Material and process costs of an adhesive layer 4 is avoided is an advantage in these cases, and the most important is the degradation of glue/colloid can be totally prevented. The embodiment shown in FIG. 6 has the same structure as the embodiment shown in FIGS. 1A and 1B except for the adhesive layer 4. However, packaged chips (flip chips or wire-bonding chips), shapes of the transparent cap 5, convex top surface S1 of the transparent cap 5, planar top surface S1 of the transparent cap 5, and etc. are not limited, and it can be applied to different packaging structures depending on different needs.

The present invention can be also applied to a conventional flip chip with or without a cavity structure, wherein a flip chip includes two electrodes being directly contacted with two electrodes 12 respectively. Other structural features/limitations are similar to the embodiments provided above, and detailed illustrations are omitted for avoiding verbosity.

Therefore, the present invention provides an ultraviolet light-emitting diode (UV LED) able to be applied to all types of LED chips, especially for UV LED chips having a wavelength below 450 nm, in order to prevent problems of degradation in the conventional packaging structures, provide better and longer protection, and extend life times of the products.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An ultraviolet light-emitting diode (UV LED) packaging structure, comprising:
a substrate having an electrode;
an UV LED chip placed on the substrate and electrically connected to the electrode;
a transparent cap disposed on and covering the substrate and the UV chip;
a light reflective layer disposed between the substrate and the transparent cap; and
an adhesion layer disposed between the substrate and the light reflective layer, wherein the transparent cap is fixed on the substrate by the light reflective layer and the adhesion layer.

2. The ultraviolet light-emitting diode (UV LED) packaging structure according to claim 1, wherein the light reflective layer contacts with the transparent cap.

3. The ultraviolet light-emitting diode (UV LED) packaging structure according to claim 1, wherein the light reflective layer is made of metal.

4. The ultraviolet light-emitting diode (UV LED) packaging structure according to claim 3, wherein the adhesive layer is made of metal and eutectic bonding with the light reflective layer.

5. The ultraviolet light-emitting diode (UV LED) packaging structure according to claim 1, wherein the adhesive layer is made of polymer resin and adhesively bonded to the light reflective layer.

6. The ultraviolet light-emitting diode (UV LED) packaging structure according to claim 1, wherein the transparent cap has a first trench and the UV LED chip is inside the first trench.

7. The ultraviolet light-emitting diode (UV LED) packaging structure according to claim 6, wherein the transparent cap has a bottom surface contacts with the substrate via the light reflective layer and the adhesion layer, and a portion of the bottom surface inside the first trench is separated from the substrate, the light reflective layer and the adhesion layer.

8. The ultraviolet light-emitting diode (UV LED) packaging structure according to claim 1, wherein the substrate further comprises a cavity structure surrounding the UV LED chip.

9. The ultraviolet light-emitting diode (UV LED) packaging structure according to claim 8, wherein
the substrate further comprises a carrier and the electrodes, where the electrodes penetrate through the carrier to electrically connect two opposite sides of the carrier; and
the cavity structure is directly contacted with the electrodes and separated from the carrier.

10. The ultraviolet light-emitting diode (UV LED) packaging structure according to claim 8, wherein the transparent cap has a second trench and the UV LED chip and the cavity structure are inside the second trench.

11. The ultraviolet light-emitting diode (UV LED) packaging structure according to claim 8, wherein the transparent cap has a planar surface close to the substrate.

12. The ultraviolet light-emitting diode (UV LED) packaging structure according to claim 11, wherein the adhesive layer is directly contacted with a top surface of the cavity structure.

13. The ultraviolet light-emitting diode (UV LED) packaging structure according to claim 8, wherein a side of the cavity structure has a concaved portion formed thereon, and a side of the transparent cap close to the cavity structure has a protrusion portion formed thereon corresponding to the concaved portion.

14. The ultraviolet light-emitting diode (UV LED) packaging structure according to claim 13, wherein the protrusion portion and the concaved portion are ring shape.

15. The ultraviolet light-emitting diode (UV LED) packaging structure according to claim 13, wherein the adhesive layer is in the concaved portion and the light reflective layer is on the protrusion portion.

16. The ultraviolet light-emitting diode (UV LED) packaging structure according to claim 15, wherein the adhesive layer is only disposed on a bottom surface of the concaved portion, and the light reflective layer is only disposed on a top surface of the protrusion portion.

17. The ultraviolet light-emitting diode (UV LED) packaging structure according to claim 1, wherein a light wavelength emitted from the UV LED chip is below 450 nm.

18. The ultraviolet light-emitting diode (UV LED) packaging structure according to claim 1, wherein the transparent cap has a convex surface away from the substrate.

19. An ultraviolet light-emitting diode (UV LED) packaging structure, comprising:
a substrate having an electrode;
an UV LED chip disposed on the substrate and electrically connected to the electrode;
a transparent cap disposed on and covering the substrate and the UV chip; and
a metal layer disposed between the substrate and the transparent cap, wherein the transparent cap is eutectic bonding with the electrode.

20. The ultraviolet light-emitting diode (UV LED) packaging structure according to claim 19, wherein the transparent cap has a trench, and the UV LED chip is inside the trench.

21. The ultraviolet light-emitting diode (UV LED) packaging structure according to claim 20, wherein the transparent cap has a bottom surface contacts with the substrate via the metal layer, and a portion of the bottom surface inside the first trench is separated from the substrate and the metal layer.

22. The ultraviolet light-emitting diode (UV LED) packaging structure according to claim 19, wherein
the substrate further comprises a carrier, and the electrode is fix on and penetrates through the carrier to electrically connect two opposite sides of the carrier; and
the metal layer is separated from the carrier.

23. The ultraviolet light-emitting diode (UV LED) packaging structure according to claim 19, wherein the transparent cap has a convex surface away from the substrate.
